(19) United States
(12) Patent Application Publication
(10) Pub. No.: US 2021/0399253 A1
(43) Pub. Date: Dec. 23, 2021

(54) DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Kan WANG, Wuhan (CN)

(21) Appl. No.: 17/053,777

(22) PCT Filed: Jun. 30, 2020
(86) PCT No.: PCT/CN2020/099389

§ 371 Date: Nov. 8, 2020

(30) Foreign Application Priority Data
Jun. 17, 2020 (CN) 202010552601.9

(51) Int. Cl. H01L 51/52

(52) U.S. Cl. CPC H01L 51/525; H01L 51/5253

(57) ABSTRACT

The present invention discloses a display panel, including an array substrate, a spacer, a functional layer, and an encapsulation layer. The array substrate includes an array layer and an inorganic structure layer. The spacer includes a first surface and a second surface, which are opposite to each other. The second surface is attached to a surface of the inorganic structure layer away from the array layer. An area of the first surface is greater than an area of the second surface.

### FIELD OF INVENTION

The present invention is related to the field of display technology, and specifically, to a display panel.

### BACKGROUND OF INVENTION

Organic light-emitting diode (OLED) display screens are self-luminous display devices which can take advantage of self-luminous characteristics of organic light-emitting materials when a voltage is applied, and do not require an additional backlight. Hence, they have characteristics of lightweight and thinness. Also, as organic materials are flexible and easy to bend, and are suitable for development of flexible and foldable display screens, the OLED display screens occupy an increasing proportion in a display field.

Currently, a light-emitting layer in an OLED device is generally prepared by a thermal evaporation method. Red, green, and blue light-emitting materials are vapor-deposited into their respective subpixel regions through a fine metal mask (FMM) to prevent the organic light-emitting materials from overlapping and mixing colors, resulting in a poor display. Under normal circumstances, the FMM is closely attached to a surface of a substrate through an action of an external magnetic field. In order to prevent the substrate from being damaged by the FMM, some spacers are generally disposed on a surface of a pixel defining layer (PDL) to separate the substrate and the FMM. However, during a manufacturing process of the OLED device, handling of the substrate and the FMM may cause the FMM to crush and scratch the spacers, resulting in poor encapsulation of the spacers, formation of intrusion channels for water and oxygen, and poor encapsulation of the OLED device.

### SUMMARY OF INVENTION

A purpose of the present invention is to solve a technical problem of a poor encapsulating effect of a display in the prior art.

In order to achieve the above purpose, the present invention provides a display panel, including: an array substrate including an array layer and an inorganic structure layer disposed on the array layer; a spacer including a first surface and a second surface, wherein the second surface is attached to a surface of the inorganic structure layer away from the array layer, an area of the first surface is greater than an area of the second surface, and a projection of the first surface on the inorganic structure layer fully covers a projection of the second surface on the inorganic structure layer; a functional layer attached to the surface of the inorganic structure layer away from the array layer and the first surface of the spacer; and an encapsulation layer covering the spacer and the functional layer.

Furthermore, on a side of the inorganic structure layer away from the array layer, a gap is provided between the spacer and the functional layer, and a part of the encapsulation layer is filled into the gap.

Furthermore, material of the inorganic structure layer includes at least one of silicon nitride, silicon oxide, silicon oxynitride, or aluminum oxide. The inorganic structure layer is a single-layer structure or a laminated structure with at least two layers.

Furthermore, the display panel further includes an organic structure layer disposed between the inorganic structure layer and the array layer.

Furthermore, the organic structure layer includes a pixel defining layer disposed on a surface of a side of the array layer.

Furthermore, the display panel further includes an organic structure layer disposed on the surface of the inorganic structure layer away from the array layer.

Furthermore, the organic structure layer includes: a planarization layer disposed on the surface of the inorganic structure layer away from the array layer; and a pixel defining layer disposed on a surface of the planarization layer away from the inorganic structure layer.

Furthermore, the display panel further includes a first through hole passing through the pixel defining layer, wherein the functional layer extends to an inner sidewall of the first through hole; and a light-emitting layer disposed in the first through hole and the array layer.

Furthermore, a thickness of the spacer ranges from 1 nm to 10 μm; and a width of the spacer ranges from 0.1 nm to 10 μm.

Furthermore, the display panel further includes a second through hole passing through the pixel defining layer and the planarization layer, wherein the functional layer extends to an inner sidewall of the third through hole.

Technical effects of the present invention are: closely attaching the spacer to the inorganic structure layer to prevent intrusion of external water and oxygen, and forming a complete encapsulation of the inorganic structure layer and the encapsulation layer to improve the encapsulating effect and increase yield of the display panel.

### DESCRIPTION OF DRAWINGS

The following describes specific embodiments of the present invention in detail with reference to the accompanying drawings, which will make technical solutions and other beneficial effects of the present invention obvious.

FIG. 1 is a structural diagram of a display panel of a first embodiment.

FIG. 2 is a structural diagram of a display panel of a first embodiment.

### REFERENCE SIGNS

array substrate 1, spacer 2, functional layer 3, encapsulation layer 4, array layer 11, organic structure layer 12, inorganic structure layer 13, planarization layer 121, pixel defining layer 122, first surface 21, second surface 22, light-emitting layer 31, first through hole 51, second through hole 52.

### DETAILED DESCRIPTION OF PREFERRED EMBODIMENTS

The technical solution of the present invention embodiment will be clarified and completely described with reference accompanying drawings in embodiments of the present invention embodiment. Obviously, the present invention described parts of embodiments instead of all of the embodiments. Based on the embodiments of the present invention, other embodiments which can be obtained by a skilled in the art without creative efforts fall into the protected scope of the of the present invention.

In the description of the present invention, it should be explained that the terms “center”, “portrait”, “transverse”, “length”, “width”, “thickness”, “upper”, “lower”, “front”, the directions or positional relationships indicated by “back”, “left”, “right”, “vertical”, “horizontal”, “top”, “bottom”, “inside”, “outside”, etc. are based on the drawings. The orientation or positional relationship is only for the convenience of describing the present invention and simplifying the description, and does not indicate or imply that the device or element referred to must have a specific orientation, structure and operation in a specific orientation, and should not be viewed as limitations of the present invention. In addition, terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present invention, the meaning of “multiple” is two or more, unless specifically defined otherwise.

In the description of the present invention, it should be explained that terms “installation”, “link”, and “connection” should be understood broadly, unless explicitly stated and limited otherwise. For example, connection can be fixed connection or removable or integral connection, can be mechanical connection, electrical connection or mutual communication, can be direct connection or indirect connection through an intermedium, or can be the internal communication between two components or the mutual reaction between two components. For a skilled person in the art, the specific meanings of the above terms of the present invention can be understood according to practical situations.

In the present invention, unless explicitly stated and limited, the first feature is “on” or “under” the second feature may refer to that the first feature and second feature are directly contact, or are indirectly through another feature between them. Moreover, the first feature is “above”, “upon”, and “upper” the second feature, including that the first feature is directly above and obliquely above the second feature refers to that t the first feature is higher in level than the second feature. The first feature is “below”, “down”, and “under” of the second feature refers to that the first feature is directly below or obliquely below the second feature, or merely refers to that the first feature is horizontally lower than the second feature.

The following invention provides many different embodiments or examples for implementing different structures of the present invention. To simplify the invention of the present invention, the components and settings of specific examples are described below. Obviously, these are merely examples instead of limitation of the present invention. Furthermore, the present invention may repeat reference numbers and/or reference letters in different examples, and such repetition is for the purpose of simplicity and clarity, and does not indicate the relationship between the various embodiments and/or settings. Moreover, the present invention provides examples of various specific processes and materials, but the applicability of other processes and/or invention of other materials may be appreciated by a person skilled in the art.

### First Embodiment

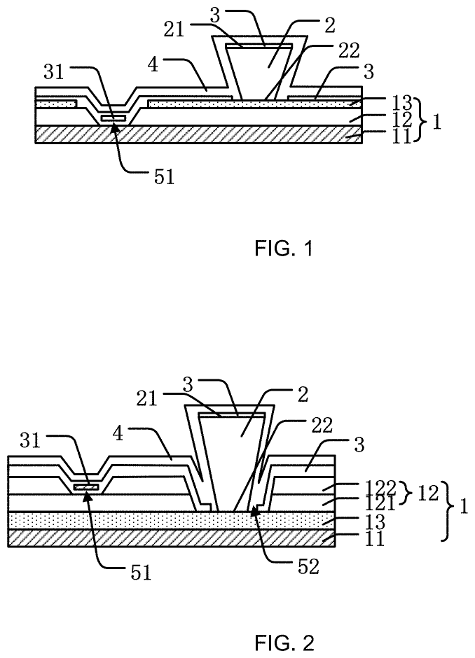

Specifically, please refer to FIG. 1, a display panel provided by an embodiment of the present invention includes an array substrate 1, a spacer 2, a functional layer 3, and an encapsulation layer 4.

The array substrate 1 is configured to control circuit switches. The array substrate 1 includes an array layer 11, an organic structure layer 12, and an inorganic structure layer 13.

The organic structure layer 12 is disposed on an upper surface of the array layer 11. In this embodiment, the organic structure layer 12 can be a pixel defining layer, which is configured to define size of the light-emitting layer. In other embodiments, the organic structure layer 12 can also be a planarization layer. The organic structure layer 12 is provided with a first through hole 51, which passes through the organic structure layer 12 to provide a channel for the light-emitting layer.

The inorganic structure layer 13 is disposed on an upper surface of the organic structure layer 12 and functions as an encapsulation barrier layer. Material of the inorganic structure layer 13 includes at least one of silicon nitride (SiNx), silicon oxide (SiOx), silicon oxynitride (SiOxNy), or aluminum oxide (AlOx). The inorganic structure layer 13 is a single-layer structure or a laminated structure with at least two layers. A thickness of the inorganic structure layer 13 ranges from 1 nm to 10 μm. The inorganic structure layer 13 does not cover the first through hole 51 to prevent a luminous effect of the light-emitting layer from being affected.

The spacer 2 includes a first surface 21 and a second surface 22, which are opposite to each other. The second surface 22 is attached to an upper surface of the inorganic structure layer 13. An area of the first surface 21 is greater than an area of the second surface 22. A projection of the first surface 21 on the inorganic structure layer 13 fully covers a projection of the second surface 22 on the inorganic structure layer 13. Material of the spacer 2 is an organic material. A longitudinal section of the spacer 2 is trapezoidal, its bottom side is the first surface 21, and its top side is the second surface 22. According to characteristics of a trapezoid, a length of the bottom side is longer than a length of the top side. Because a surface of the spacer 2 is flat and fixed in shape, this also satisfies the area of the first surface 21 of the spacer 2 being greater than the area of the second surface 22 of the spacer 2.

The functional layer 3 is disposed on the upper surface of the inorganic structure layer 13 and an upper surface of the first surface 21 of the spacer 2. The functional layer 3 extends to a bottom and an inner sidewall of the first through hole 51. Because the area of the first surface 21 of the spacer 2 is greater than the area of the second surface 22 of the spacer 2, this can ensure that the functional layer 3 exhibits a direct cover effect in a top view, and that an entire surface of the array substrate 1 is covered with the functional layer 3. Also, the luminous effect of the display panel is ensured, so as to prevent an uneven display.

The light-emitting layer 31 is disposed in the first through hole 51 and the functional layer 3. The functional layer 3 includes a hole injection layer, a hole transport layer, an electron transport layer, an electron injection layer, a cathode layer, etc. The hole transport layer and the hole injection layer are disposed under the light-emitting layer 31 and are connected to an anode layer of the array layer 11 for transporting holes. The electron transport layer, the electron injection layer, and the cathode layer are disposed above the light-emitting layer 31 for transporting electrons. The electrons and the holes emit light after colliding in the light-emitting layer 31, so as to achieve a light-emitting function.

The encapsulation layer 4 covers the spacer 2 and the functional layer 3 to achieve a technical effect of blocking external water and oxygen, and forms a complete closed structure with the inorganic structure layer 13, thereby forming a complete encapsulation for the spacer 2 and the functional layer 3 above. A gap is provided between the spacer 2 and the functional layer 3. The encapsulation layer 4 is filled into the gap. Materials of the encapsulation layer 4 includes at least one of silicon nitride (SiNx), silicon oxide (SiOx), silicon oxynitride (SiOxNy), or aluminum oxide (AlOx).

Technical effects of the present invention are: closely attaching the spacer to the inorganic structure layer to prevent intrusion of external water and oxygen, and forming a complete encapsulation of the inorganic structure layer and the encapsulation layer to improve the encapsulating effect and increase yield of the display panel.

### Second Embodiment

As shown in FIG. 2, a display panel provided by an embodiment of the present invention includes an array substrate 1, a spacer 2, a functional layer 3, and an encapsulation layer 4.

The array substrate 1 is configured to control circuit switches. The array substrate 1 includes an array layer 11, an organic structure layer 12, and an inorganic structure layer 13.

The inorganic structure layer 13 is disposed on an upper surface of the array layer 11 and functions as an encapsulation barrier layer. Material of the inorganic structure layer 13 includes at least one of silicon nitride (SiNx), silicon oxide (SiOx), silicon oxynitride (SiOxNy), or aluminum oxide (AlOx). The inorganic structure layer 13 is a single-layer structure or a laminated structure with at least two layers. A thickness of the inorganic structure layer 13 ranges from 1 nm to 10 μm. The inorganic structure layer 13 does not cover the first through hole 51 to prevent a luminous effect of the light-emitting layer from being affected.

The organic structure layer 12 is disposed on an upper surface of the inorganic structure layer 13. In this embodiment, the inorganic structure layer 13 can be a planarization layer 121 and a pixel defining layer 122. The planarization layer 121 is disposed on the upper surface of the inorganic structure layer 13. The pixel defining layer 122 is disposed on an upper surface of the planarization layer 121. The pixel defining layer 122 is configured to define size of the light-emitting layer 31. The pixel defining layer 122 is provided with a first through hole 51, which passes through the pixel defining layer 122 to provide a channel for the light-emitting layer.

The spacer 2 is disposed in the second through hole 52. The spacer 2 includes a first surface 21 and a second surface 22, which are disposed opposite to each other. The second surface 22 is attached to the upper surface of the inorganic structure layer 13. An area of the first surface 21 is greater than an area of the second surface 22. A projection of the first surface 21 on the inorganic structure layer 13 fully covers a projection of the second surface 22 on the inorganic structure layer 13. Material of the spacer 2 is an organic material. A longitudinal section of the spacer 2 is trapezoidal, its bottom side is the first surface 21, and its top side is the second surface 22. According to characteristics of a trapezoid, a length of the bottom side is longer than a length of the top side. Because a surface of the spacer 2 is flat and fixed in shape, this also satisfies the area of the first surface 21 of the spacer 2 being greater than the area of the second surface 22 of the spacer 2.

The functional layer 3 is disposed on an upper surface of the pixel defining layer 122 and an upper surface of the first surface 21 of the spacer 2. The functional layer 3 extends to a bottom and an inner sidewall of the first through hole 51 and further extends to a bottom of the second through hole 52. Because the area of the first surface 21 of the spacer 2 is greater than the area of the second surface 22 of the spacer 2, this can ensure that the functional layer 3 exhibits a direct cover effect in a top view, and that an entire surface of the array substrate 1 is covered with the functional layer 3. Also, the luminous effect of the display panel is ensured, so as to prevent an uneven display.

The light-emitting layer 31 is disposed in the first through hole 51 and the functional layer 3. The functional layer 3 includes a hole injection layer, a hole transport layer, an electron transport layer, an electron injection layer, a cathode layer, etc. The hole transport layer and the hole injection layer are disposed under the light-emitting layer 31 and are connected to an anode layer of the array layer 11 for transporting holes. The electron transport layer, the electron injection layer, and the cathode layer are disposed above the light-emitting layer 31 for transporting electrons. The electrons and the holes emit light after colliding in the light-emitting layer 31, so as to achieve a light-emitting function.

The encapsulation layer 4 covers the spacer 2 and the functional layer 3. A gap is provided between the spacer 2 and the functional layer 3. The encapsulation layer 4 is filled into the gap to achieve a technical effect of blocking external water and oxygen, and forms a complete closed structure with the inorganic structure layer 13, thereby forming a complete encapsulation for the spacer 2 and the functional layer 3 above. Materials of the encapsulation layer 4 includes at least one of silicon nitride (SiNx), silicon oxide (SiOx), silicon oxynitride (SiOxNy), or aluminum oxide (AlOx).

Technical effects of the present invention are: closely attaching the spacer to the inorganic structure layer to prevent intrusion of external water and oxygen, and forming a complete encapsulation of the inorganic structure layer and the encapsulation layer to improve the encapsulating effect and increase yield of the display panel.

In the above embodiments, the descriptions of the various embodiments are different in emphases, for contents not described in detail, please refer to related description of other embodiments.

The display panel provided by embodiments of the present invention is described in detail above, and the description of embodiments above is only for helping to understand technical solutions of the present invention and its core idea. Understandably, for a person of ordinary skill in the art can make various modifications of the technical solutions of the embodiments of the present invention above. However, it does not depart from the scope of the technical solutions of the embodiments of the present invention.

1. A display panel, comprising:
an array substrate comprising an array layer and an inorganic structure layer disposed on the array layer;
a spacer comprising a first surface and a second surface, wherein the second surface is attached to a surface of the inorganic structure layer away from the array layer, an area of the first surface is greater than an area of the second surface, and a projection of the first surface on the inorganic structure layer fully covers a projection of the second surface on the inorganic structure layer;
a functional layer attached to the surface of the inorganic structure layer away from the array layer and the first surface of the spacer; and
an encapsulation layer covering the spacer and the functional layer.

2. The display panel according to claim 1, wherein on a side of the inorganic structure layer away from the array layer, a gap is provided between the spacer and the functional layer, and a part of the encapsulation layer is filled into the gap.

3. The display panel according to claim 1, wherein material of the inorganic structure layer comprises at least one of silicon nitride, silicon oxide, silicon oxynitride, or aluminum oxide; and
the inorganic structure layer is a single-layer structure or a laminated structure with at least two layers.

4. The display panel according to claim 1, further comprising:
an organic structure layer disposed between the inorganic structure layer and the array layer.

5. The display panel according to claim 4, wherein the organic structure layer comprises:
a pixel defining layer disposed on a surface of a side of the array layer.

6. The display panel according to claim 1, further comprising:
an organic structure layer disposed on the surface of the inorganic structure layer away from the array layer.

7. The display panel according to claim 6, wherein the organic structure layer comprises:
a planarization layer disposed on the surface of the inorganic structure layer away from the array layer; and
a pixel defining layer disposed on a surface of the planarization layer away from the inorganic structure layer.

8. The display panel according to claim 5, further comprising:
a first through hole passing through the pixel defining layer, wherein the functional layer extends to an inner sidewall of the first through hole; and
a light-emitting layer disposed in the first through hole and the array layer.

9. The display panel according to claim 7, further comprising:
a first through hole passing through the pixel defining layer, wherein the functional layer extends to an inner sidewall of the first through hole; and
a light-emitting layer disposed in the first through hole and the array layer.

10. The display panel according to claim 1, wherein a thickness of the spacer ranges from 1 nm to 10 μm; and
a width of the spacer ranges from 0.1 nm to 10 μm.

11. The display panel according to claim 7, further comprising:
a second through hole passing through the pixel defining layer and the planarization layer, wherein the functional layer extends to an inner sidewall of the second through hole.
